(19) United States
(12) Patent Application Publication
(10) Pub. No.: US 2007/0018259 A1
(43) Pub. Date: Jan. 25, 2007

(54) Dual gate electrode metal oxide semciconductor transistors

(75) Inventors: Chih-Hsin Ko, Fongshan City (TW); Yee-Chia Yeo, Singapore (SG); Wen-Chin Lee, Hsin-Chu (TW)

Correspondence Address: TUNG & ASSOCIATES, Suite 120, 838 W. Long Lake Road, Bloomfield Hills, MI, 48302, US

(73) Assignee: Taiwan Semiconductor Manufacturing Co., Ltd.

(21) Appl. No.: 11/187,271

(22) Filed: Jul. 21, 2005

(51) Int. Cl. H01L 29/94

(52) U.S. Cl. 257/410

(57) ABSTRACT

A semiconductor product includes a pair of field effect transistor device structures formed one each within a pair of doped well regions within a semiconductor substrate. The pair of field effect transistor device structures is formed with a pair of metal gate electrodes formed employing different laminated metal constructions. By correlating a work function within a metal layer within a gate electrode with a work function of a semiconductor substrate region over which it is formed, the field effect transistor devices are formed with enhanced performance.

### BACKGROUND OF THE INVENTION

1. Field of the Invention

The invention relates generally to field effect transistor devices. More particularly, the invention relates to field effect transistor devices with enhanced performance.

2. Description of the Related Art

As field effect transistor device dimensions have decreased a trend towards use of metal gate electrodes has evolved. Metal gate electrodes provide advantages over conventional polysilicon gate electrodes insofar as intrinsically they suffer from no gate depletion or dopant penetration phenomenon. Thus, field effect transistor devices formed with metal gate electrodes may typically be formed with enhanced performance.

While metal gate electrodes are thus desirable when fabricating advanced field effect transistor devices, they are nonetheless not entirely without problems. In particular metal gate electrodes are often difficult to form with optimally desirable electrical properties. The invention is directed towards that object.

### SUMMARY OF THE INVENTION

The invention provides several field effect transistor device structures having metal gate electrodes. The field effect transistor device structures are formed in paired structures, preferably as complementary metal oxide semiconductor (CMOS) paired field effect transistor device structures. The metal gate electrodes are formed with different laminated structures for each field effect transistor device within a pair of field effect transistor devices. The invention also provides for matching a work function of a metal layer within a field effect transistor device with a work function of a portion of a semiconductor substrate upon which it is formed. [Gate electrode materials should be chosen to match a work function and adjust the Vt of devices] The invention also provides for either a high dielectric constant gate dielectric material or differing dielectric materials when forming a pair of field effect transistor devices.

### BRIEF DESCRIPTION OF THE DRAWINGS

The objects, features and advantages of the invention are understood within the context of the Description of the Preferred Embodiments, as set forth below. The Description of the Preferred Embodiments is understood within the context of the accompanying drawings, which form a material part of this disclosure, wherein.

FIG. 1a, FIG. 1b, FIG. 1c and FIG. 1d show a series of schematic cross-sectional diagrams illustrating the results of progressive stages in fabricating a field effect transistor device structure in accord with a first preferred embodiment of the invention.

FIG. 2 and FIG. 3 show a pair of schematic cross-sectional diagrams illustrating a pair of field effect transistor device structures in accord with alternative first preferred embodiments of the invention.

FIG. 4a, FIG. 4b, FIG. 4c, FIG. 4d and FIG. 4e show a series of schematic cross-sectional diagrams illustrating the results of progressive stages in fabricating a field effect transistor device in accord with a second preferred embodiment of the invention.

FIG. 5 and FIG. 6 show a pair of schematic cross-sectional diagrams illustrating a pair of field effect transistor device structures in accord with alternative second preferred embodiments of the invention.

FIG. 7a, FIG. 7b, FIG. 7c, FIG. 7d and FIG. 7e show a series of schematic cross-sectional diagrams illustrating the results of progressive stages in fabricating a field effect transistor device structure in accord with a third preferred embodiment of the invention.

FIG. 8 and FIG. 9 show a pair of schematic cross-sectional diagrams illustrating a pair of field effect transistor device structures in accord with alternative third preferred embodiments of the invention.

FIG. 10a, FIG. 10b, FIG. 10c, FIG. 10d and FIG. 10e show a series of schematic cross-sectional diagrams illustrating the results of progressive stages in forming a field effect transistor device structure in accord with a fourth preferred embodiment of the invention.

FIG. 11 and FIG. 12 show a pair of schematic cross-sectional diagrams illustrating a pair of field effect transistor device structures in accord with alternative fourth preferred embodiments of the invention.

### DESCRIPTION OF THE PREFERRED EMBODIMENTS

The invention provides several field effect transistor device structures having metal gate electrodes. The field effect transistor device structures are formed in paired structures, preferably as complementary metal oxide semiconductor (CMOS) paired field effect transistor device structures. The metal gate electrodes are formed with different laminated structures for each field effect transistor device within a pair of field effect transistor devices. [Comment: The metal gate work function of a n-channel transistor, for example, substantially matches the work function of n-type silicon, which is found in the source/drain region of the transistor, and not a portion of the semiconductor substrate upon which it is formed. Moreover, the metal gate work function in a n-channel transistor may not exactly match the work function of n-type silicon. ‘Substantial matching’ would be a better word to use. It is very important to note that the metal gate work function should not be the same as the work function of the well region. It should also be noted that the ‘choice’ of appropriate metal gate work functions for n- or p-channel transistors is well known and is not a novelty of this invention.] The invention also provides for either a high dielectric constant gate dielectric material or differing dielectric materials when forming a pair of field effect transistor devices.

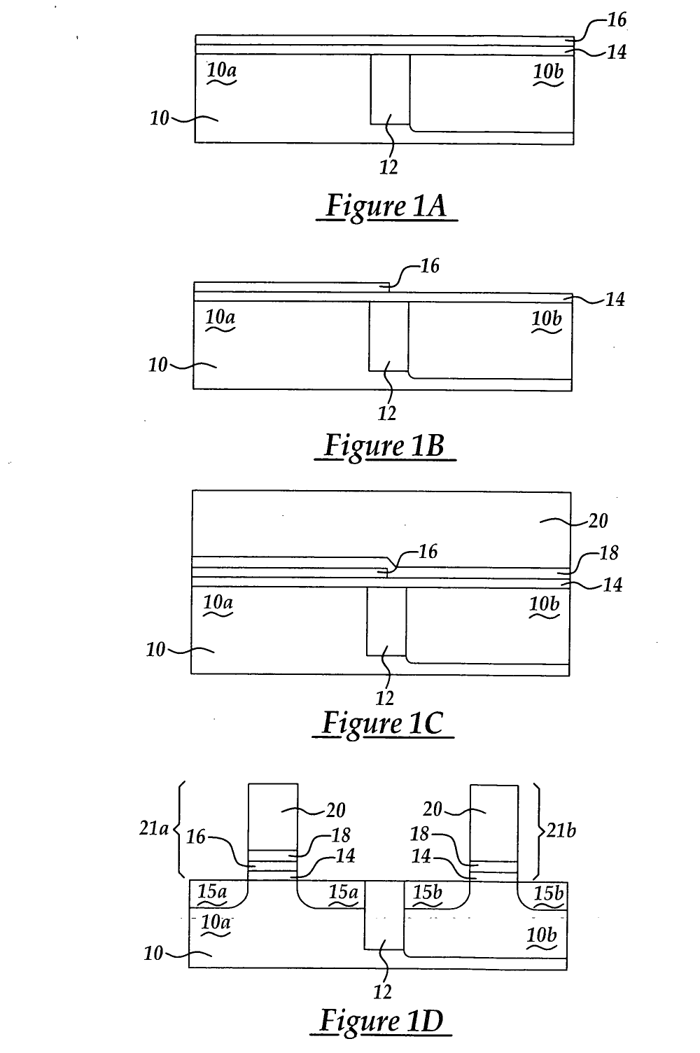

FIG. 1a to FIG. 1d show a series of schematic cross-sectional diagrams illustrating the results of progressive stages in fabricating a field effect transistor device structure in accord with a first preferred embodiment of the invention.

FIG. 1a shows a semiconductor substrate 10. The semiconductor substrate 10 has a first doped well region 10a and a second doped well region 10b that are separated by an isolation region 12. A blanket high dielectric constant gate dielectric material layer 14 is formed upon the semiconductor substrate 10 including the first doped well region 10a and the second doped well region 10b. A blanket first gate electrode material layer 16 is formed upon the blanket high dielectric constant gate dielectric material layer 14.

The semiconductor substrate 10 may be formed of semiconductor materials including but not limited to bulk silicon semiconductor materials, silicon on insulator semiconductor materials, strained silicon semiconductor materials on graded silicon germanium alloy materials and silicon germanium alloy semiconductor materials. Typically, the semiconductor substrate 10 is a silicon semiconductor substrate. The semiconductor substrate 10 may have either dopant polarity, any of several dopant concentrations and any of several crystallographic orientations.

The first doped well region 10a and the second doped well region 10b are typically of opposite polarity, although such is not required within the invention. Typically, each of the first doped well region 10a and the second doped well region 10b is doped with an appropriate dopant at a concentration of from about 1E12 to about 1E13 dopant atoms per cubic centimeter.

The isolation region 12 is typically a shallow trench isolation region, although the invention is not limited to shallow trench isolation regions.

The blanket high dielectric constant gate dielectric material layer 14 may be formed from any of several higher dielectric constant dielectric materials, although certain aspects of the invention may also be operative when employing generally lower dielectric constant dielectric materials for gate dielectric layers. Within the invention, lower dielectric constant dielectric materials are intended as having a dielectric constant less than about 8. Examples include silicon oxide dielectric materials, silicon nitride dielectric materials and silicon oxynitride dielectric materials. Higher dielectric constant dielectric materials have a dielectric constant greater than about 8. Such dielectric materials may include, but are not limited to aluminum oxide dielectric materials, hafnium oxide dielectric materials, zirconium oxide dielectric materials, hafnium oxynitride dielectric materials, hafnium silicon oxynitrde dielectric materials, hafnium silicate dielectric materials, zirconium silicate dielectric materials, lanthanum oxide dielectric materials and composites thereof. Also included are transition metal oxide dielectric materials. Typically, the blanket high dielectric constant gate dielectric material layer 14 is formed to a thickness of from about 10 to about 200 angstroms, although the invention is not so limited.

The blanket first gate electrode material layer 16 may also be formed from any of several materials. The materials may include but are not limited to metal, metal nitride and metal silicide materials. The foregoing materials are intended as [symbol] \textcircled{M}⅓^{N}_{L}⅝⅝ 0/00⅝⅛^{N}_{L}C_{R} 13/8 5/8[It means gate electrode stacks with metal as under gate material to eliminate poly depletion effect and also for Vt adjustment and then follow by poly or second material (for example: NMOS). The second material can be used for second gate electrode (for example: PMOS) ] in accord with the invention. Particularly excluded are doped polysilicon materials that are susceptible to a depletion effect. Some representative examples of included [symbol] metals include titanium, molybdenum, tantalum, aluminum, titanium nitride, ruthenium, molybdenum silicide, niobium, zirconium and tantalum silicide. Additional examples include nickel, molybdenum nitride, tantalum nitride, ruthenium oxide, magnesium, platinum, palladium and iridium. Further examples include tungsten silicide, tantalum silicide, molybdenum silicide, nickel silicide, cobalt silicide and titanium silicide.

FIG. 1b shows the results of patterning the blanket first gate electrode material layer 16 to form a patterned first gate electrode material layer 16.

The patterning may be effected employing methods as are conventional in the semiconductor product fabrication art. Such methods will typically include photolithographic and etch methods that include either wet chemical or dry plasma etchants.

FIG. 1c shows the results of forming a blanket second gate electrode material layer 18 upon exposed portions of the patterned first gate electrode material layer 16 and the blanket high dielectric constant gate dielectric material layer 14 as illustrated in FIG. lb. FIG. 1c also shows a blanket third gate electrode material layer 20 formed upon the blanket second gate electrode material layer 18.

The blanket second gate electrode material layer 18 may be formed of a gate electrode material selected from the same groups as the blanket first gate electrode material layer 16. The blanket third gate electrode material layer 20 is typically formed from a metal or a silicide. The metal may be selected from the group consisting of molybdenum, aluminum nickel, tungsten and cobalt metals. The silicide, which is also intended as a [symbol] gate electrodein accord with the invention, may be selected from the group consisting of tungsten, tantalum, molybdenum, nickel, cobalt and titanium silicides. In accord with further discussion below, each of the blanket first gate electrode material layer 16, the blanket second gate electrode material layer 18 and the blanket third gate electrode material layer 20 is formed of a separate gate electrode material.

FIG. 1d first shows the results of patterning the layered structure as illustrated in FIG. 1c to form a pair of gate electrode stack layers 21a and 21b. A first gate electrode stack layer 21a is formed with respect to the first doped well region 10a. It includes a patterned high dielectric constant gate dielectric material layer 14, a twice patterned first gate electrode material layer 16, a patterned second gate electrode material layer 18 and a patterned third gate electrode material layer 20. A second gate electrode stack layer 21b is formed with respect to the second doped well 10b. It includes a patterned high dielectric constant gate dielectric material layer 14, a patterned second gate electrode material layer 18 and a patterned third gate electrode material layer 20. FIG. 1d also shows a pair of first source/drain regions 15a formed within the first doped well 10a and a pair of second source/drain regions 15b formed with respect to the second doped well 10b. The two pair of source/drain regions 15a and 15b are formed employing methods and materials as are conventional in the semiconductor product fabrication art. They have appropriate polarities with respect to the pair of field effect transistors to which they are formed.

Within the first preferred embodiment of the invention, a work function of the twice patterned first gate electrode material layer 16 is selected such as to match a work function of the semiconductor substrate 10 at the location of the first doped well region 10a. [No, The workfunction of metal is dependent on well doping concentration and we can choose different material with different workfunction to adjust device's Vt.] In addition a work function of the patterned second gate electrode material layer 18 is selected to match a work function of the semiconductor substrate 10 at the location of the second doped well region 10b. Finally, a thickness of the blanket (or patterned) third gate electrode material layer 20 is selected to be at least three times thicker than the blanket (or patterned) second gate electrode material layer 18 or the blanket (or patterned) first gate electrode material layer 16. Work functions are readily measured employing methods as are conventional in the art. For example, the work function is conventionally calculated from an analysis of the flat-band voltage versus the equivalent oxide thickness (EOT).

Typically, each of the blanket first gate electrode material layer 16 and the blanket second gate electrode material layer 18 is formed to a thickness of from about 200 to about 400 angstroms. Typically, the blanket third gate electrode material layer 20 is formed to a thickness of from about 1200 to about 3000 angstroms.

By matching the work function characteristics of a gate electrode material layer and a semiconductor substrate 10 at the location of a doped well region therein for each of a pair of field effect transistor devices in accord with the first preferred embodiment of the invention, a field effect transistor device structure is formed with enhanced performance. [Same comment as in paragraph 27.]

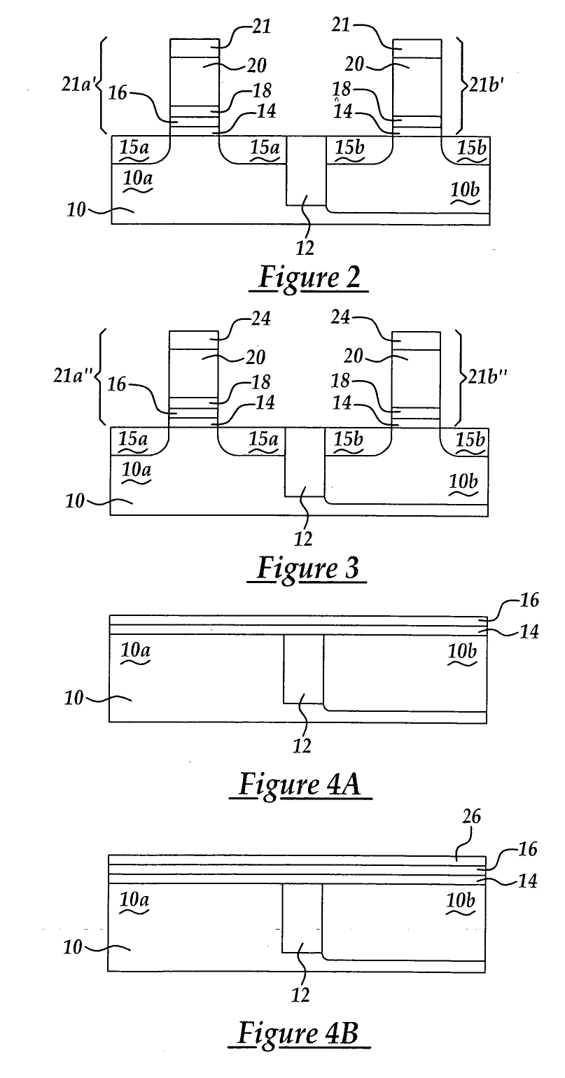

FIG. 2 and FIG. 3 show a pair semiconductor products that represents alternate variations upon the first preferred embodiment of the invention.

FIG. 2 derives from the semiconductor product of FIG. 1d, but with the addition of a pair of patterned dielectric capping layers 22 formed upon the pair of patterned third gate electrode material layers 20. The pair of patterned dielectric capping layers 22 typically serves as hard mask layers when forming a pair of gate electrode stacks 21a [symbol] and 21b. Typically, each of the pair of patterned dielectric capping layers 22 is formed to a thickness of from about 200 to about 2000 angstroms.

FIG. 3 also derives from the semiconductor product of FIG. 1d, but with the addition of a pair of metal electrodes 24 rather than the pair of dielectric capping layers 22 as illustrated in FIG. 2. The pair of metal electrodes 24 may be formed from any of several metals as are employed for forming the blanket third gate electrode material layer 20. Typically, each of the pair of metal electrodes 24 is formed to a thickness of from about 200 to about 2000 angstroms.

Although not illustrated within the foregoing schematic cross-sectional diagrams, each of the pair of gate electrode stacks within the semiconductor products may have spacer layers formed adjoining thereto. The spacer layers assist in providing proper spacing when forming lightly doped extension regions and source/drain regions.

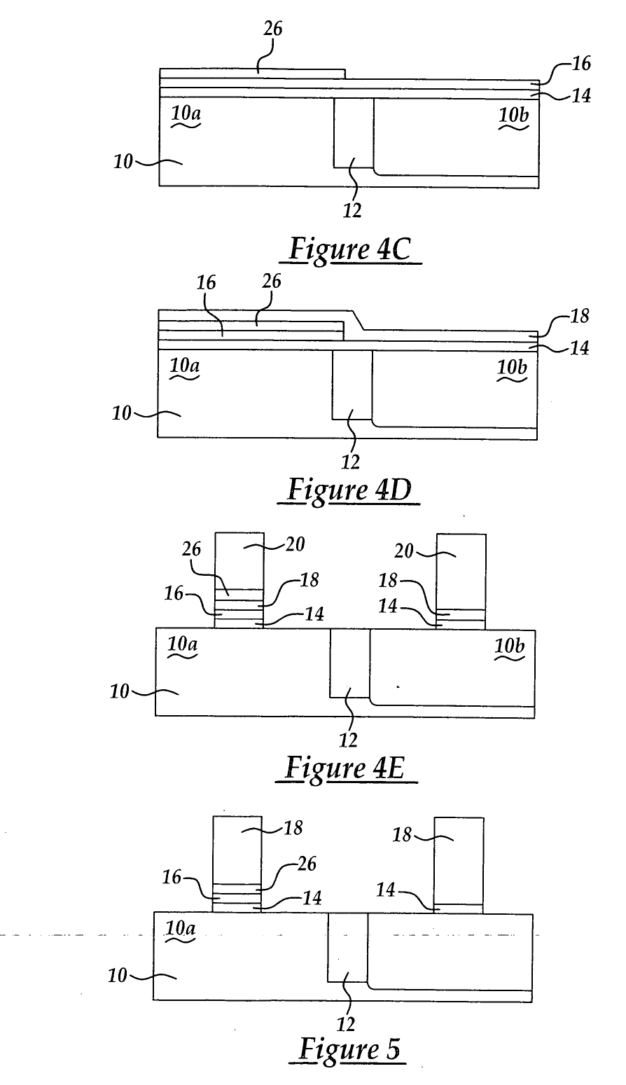

FIG. 4a to FIG. 4e show a series of schematic cross-sectional diagrams illustrating the results of progressive stages in forming a semiconductor product in accord with a second preferred embodiment of the invention.

FIG. 4a to FIG. 4e correspond generally with FIG. 1a to FIG. 1d. They also show the formation of a complementary metal oxide semiconductor (CMOS) semiconductor product type structure. Within the second preferred embodiment, the source/drain regions 15a and 15b have been omitted for clarity. They are however still present in the final semiconductor product for functionality. In contrast with the first preferred embodiment, FIG. 4b illustrates the addition of a blanket barrier layer 26 upon the blanket first gate electrode material layer 16. FIG. 4c shows a patterning of the blanket barrier layer 26 to form a patterned barrier layer 26. FIG. 4d shows a patterning of the blanket first gate electrode material layer 16 to form a patterned first gate electrode material layer 16. FIG. 4d also shows the blanket second gate electrode material layer 18 formed upon exposed surfaces of the patterned barrier layer 26, the patterned first gate electrode material layer 16 and the blanket high dielectric constant gate dielectric material layer 14. Although not specifically illustrated within FIG. 4d, a blanket third gate electrode material layer is also formed upon the blanket second gate electrode material layer 18. Finally, as illustrated in 4e, all layers are further patterned to form a pair of gate electrode stack layers that correspond generally with the pair of gate electrode stack layers s 21a and 21b as illustrated in FIG. 1d, but with the addition of the twice patterned barrier layer 26 only within the gate electrode stack that corresponds with the first doped well region 10a.

Within the second embodiment, the blanket barrier layer 26 is typically a metal selected from the group including but not limited to titanium nitride, tantalum nitride and tungsten.

FIG. 5 shows a semiconductor product related to the semiconductor product of FIG. 4e. FIG. 5 shows a semiconductor product having a patterned barrier layer 26 interposed between a patterned first gate electrode material layer 16 and a patterned second gate electrode material layer 18 within a first gate electrode stack. Absent in FIG. 5 is a pair of patterned third gate electrode material layers 20 as illustrated within FIG. 4e. In addition, the pair of patterned second gate electrode material layers 18 is formed to greater thicknesses.

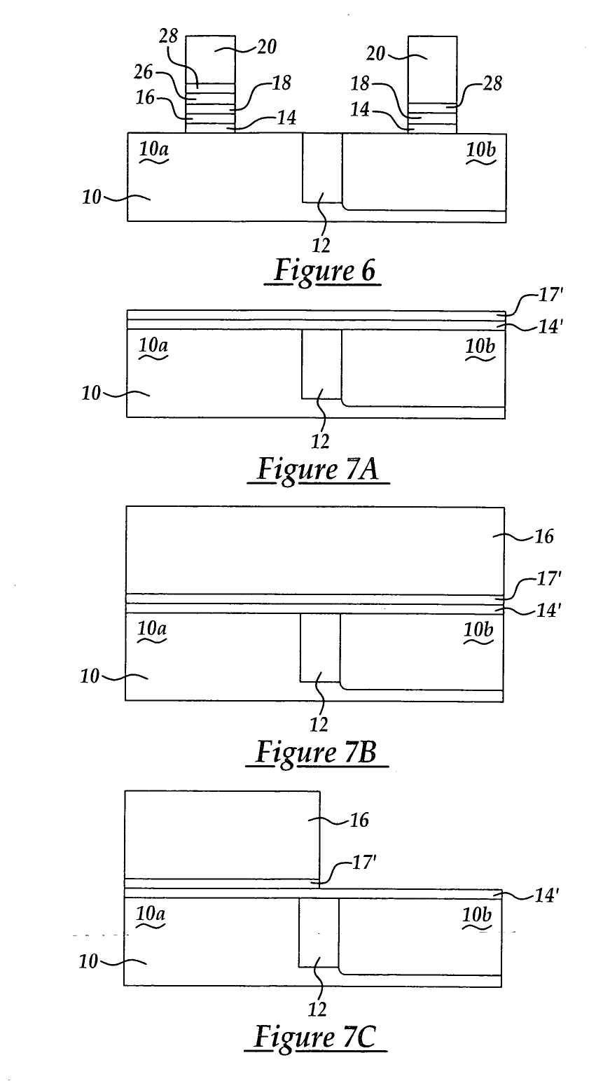

FIG. 6 shows an additional semiconductor product that incorporates a patterned second barrier layer 28 formed upon a patterned second gate electrode material layer 18 within both the first gate electrode stack (with respect to the first doped well 10a) and the second gate electrode stack (with respect to the second doped well 10b). The patterned second barrier layers 28 may be formed of materials and thickness analogous, equivalent of identical to the materials and thicknesses employed for forming the patterned first barrier layers 26.

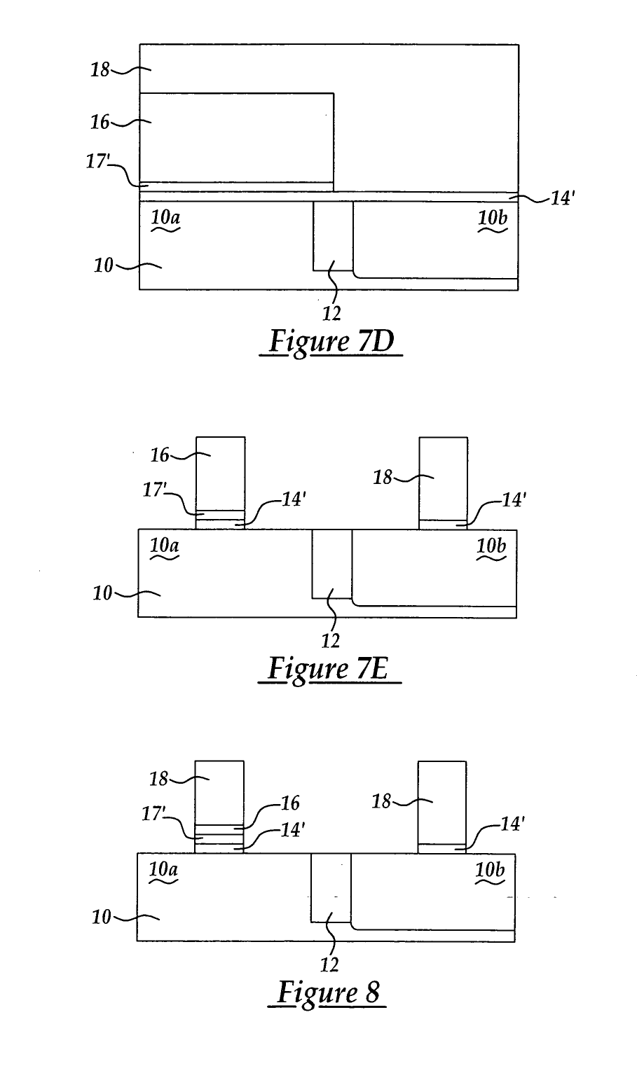

FIG. 7a to FIG. 7e show a series of schematic cross-sectional diagrams illustrating the results of progressive stages in forming a semiconductor product in accord with a third preferred embodiment of the invention.

FIG. 7a corresponds generally with FIG. 1a, but includes a blanket second gate dielectric material layer 17′ and a blanket first gate dielectric material layer 14′. Neither of the gate dielectric material layers need necessarily be formed of a high dielectric constant dielectric material, although either or both may be.

FIG. 7b shows a blanket first gate electrode material layer 16 formed upon the blanket second gate dielectric material layer 17′. FIG. 7c shows the results of patterning the blanket first gate electrode material layer 16 and the blanket second gate dielectric material layer 17′ to form a patterned first gate electrode material layer 16 and a patterned second gate dielectric material layer 17′ over the first doped well region 10a but not over the second doped well region 10b.

FIG. 7d shows a blanket second gate electrode material layer 18 formed over the semiconductor product of FIG. 7c. Finally, FIG. 7e shows the results of patterning the semiconductor product of FIG. 7d to provide a first gate electrode stack with respect to the first doped well 10a and a second gate electrode stack with respect to the second doped well 10b. The first gate electrode stack comprises a patterned first gate dielectric material layer 14′, a patterned second gate dielectric material layer 17′ and a patterned first gate electrode material layer 16. The second gate electrode stack comprises a patterned first gate electrode material layer 14′ and a patterned second gate electrode material layer 18. Thus, the first gate electrode stack includes a dual layer gate dielectric layer with a patterned first gate electrode material layer formed of a first gate electrode material, while the second gate electrode stack includes a single layer gate dielectric layer and a patterned second gate electrode material layer formed of a second gate electrode material.

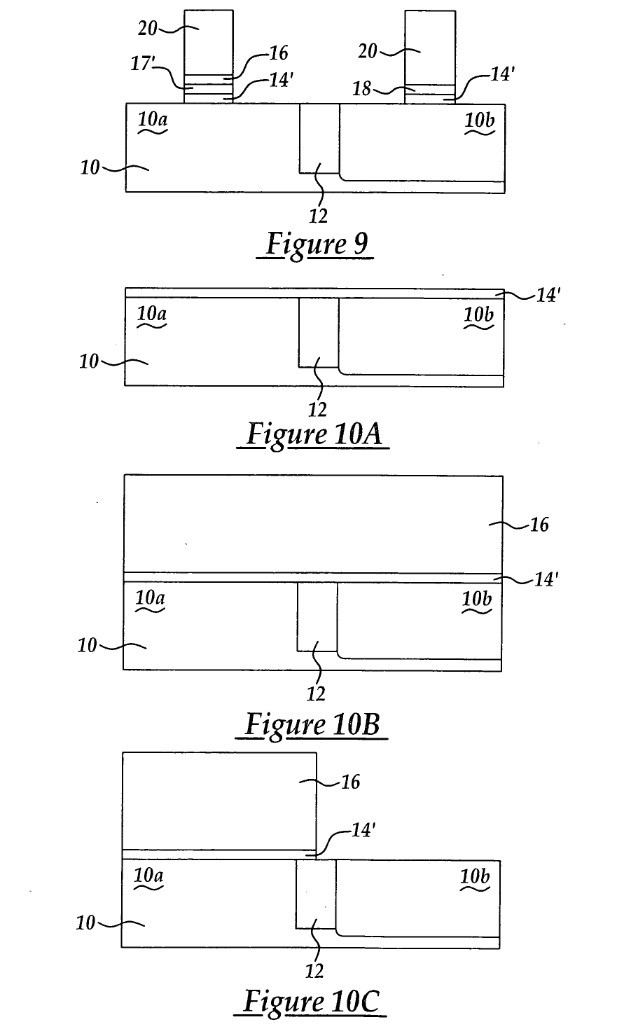

FIG. 8 and FIG. 9 show a pair of schematic cross-sectional diagrams illustrating alternate semiconductor products in accord with the third preferred embodiment of the invention.

FIG. 8 corresponds with FIG. 7e, but shows a first gate electrode stack that includes a patterned second gate electrode material layer 18 in addition to the patterned first gate electrode material layer 16, the patterned second gate dielectric material layer 17′ and the patterned first gate dielectric material layer 14′.

FIG. 9 differs by providing a first gate electrode stack including a bilayer patterned dielectric layer 14′/17′ in conjunction with a patterned first gate electrode material layer 16 and a patterned third gate electrode material layer 20. A second gate electrode stack includes a single layer gate dielectric layer 14′ in conjunction with a patterned second gate electrode material layer 18 and a patterned third gate electrode material layer 20.

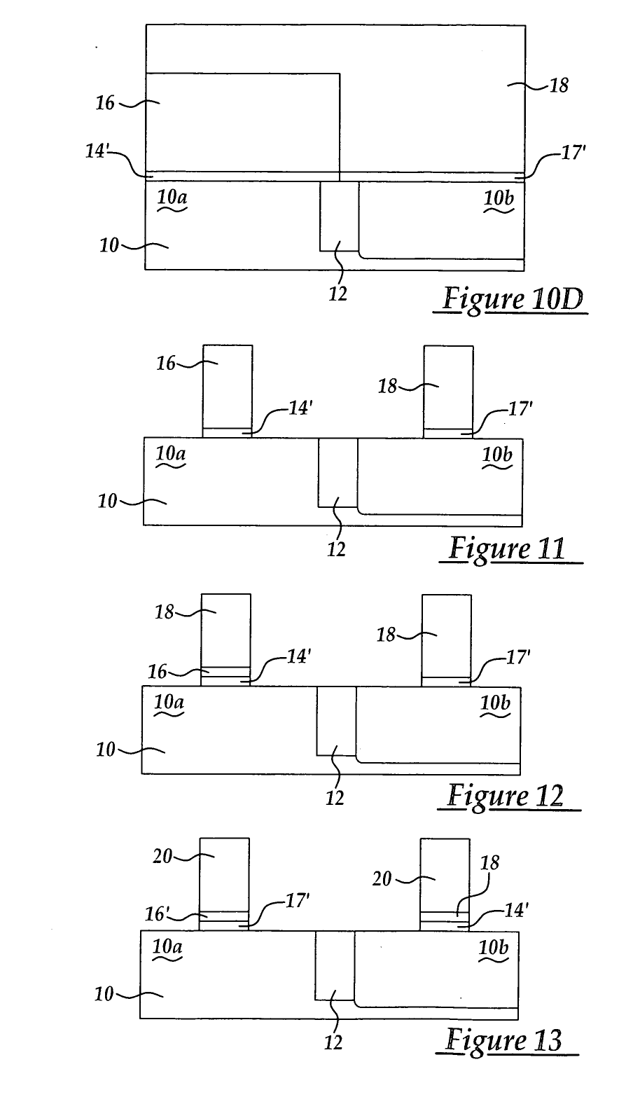

FIG. 10a to FIG. 10e show a series of schematic cross-sectional diagrams illustrating the results of progressive stages in forming a semiconductor product in accord with a fourth preferred embodiment of the invention.

FIG. 10a and FIG. 10b correspond generally with FIG. 7a and FIG. 7b, but absent the blanket second gate dielectric material layer 17′ and with a blanket first gate electrode material layer 16 formed with an increased thickness in a range of from about 1000 to about 2000 angstroms. FIG. 10c shows the results of pattering the blanket first gate electrode material layer 16 and the blanket first gate dielectric material layer 14′ to form corresponding patterned layers over the first doped well region 10a, but not over the second doped well region 10b.

FIG. 10d shows the results of forming a patterned second gate dielectric material layer 17′ upon the second doped well 10b and a blanket second gate electrode material layer 18 formed thereupon. FIG. 10e shows the results of patterning the laminated structure of FIG. 10d to provide a patterned first gate electrode material layer 16 formed upon a patterned first gate dielectric material layer 14′ formed upon the first doped well region 10a and a patterned second gate electrode material layer 18 formed upon a patterned second gate dielectric material layer 17′ formed upon the second doped well region 10b.

FIG. 11 and FIG. 12 show alternate variations of the semiconductor product of FIG. 10. FIG. 11 shows a first gate electrode stack that includes a patterned second gate electrode material layer 18 in addition to a thinner patterned first gate electrode material layer 16. FIG. 12 shows a semiconductor product having a first gate electrode stack that includes a patterned second gate dielectric material layer 17′, a patterned first gate electrode material layer 16 and a patterned third gate electrode material layer 20. A second gate electrode stack includes a patterned first gate dielectric material layer 14′, a patterned second gate electrode material layer 18 and a patterned third gate electrode material layer 20.

The preferred embodiments of the invention are illustrative of the invention rather than limiting of the invention. Revisions and modifications may be made to methods, materials, structures and dimensions of a semiconductor product in accord with the preferred embodiments of the invention while still providing a semiconductor product in accord with the invention, further in accord with the accompanying claims.

What is claimed is:

1. A semiconductor product comprising:
a semiconductor substrate having a first well of a first conductivity type and a second well of a second conductivity type;
a high-k gate dielectric layer formed upon the semiconductor substrate including the first well and the second well;
a first transistor formed with respect to the first well, the first transistor having a first gate comprising a first gate electrode material layer upon the high-k dielectric layer, a second gate electrode material layer upon the first gate electrode material and a third gate electrode material layer upon the second gate electrode material layer, the first gate electrode material layer having a first work function corresponding to the first well of the first conductivity type;
a second transistor formed with respect to the second well, the second transistor having a second gate comprising the second gate electrode material layer upon the high-k dielectric layer and the third gate electrode material layer upon the second gate electrode material layer, the second gate electrode material layer having a second work function corresponding to the second well of the second conductivity type, wherein the third gate electrode material layer is formed to a thickness of at least three times greater than the first gate electrode material layer and the second gate electrode material layer.

2. The semiconductor product of claim 1 wherein the semiconductor substrate is a silicon-on-insulator substrate.

3. The semiconductor product of claim 1 wherein the semiconductor substrate comprises a strained silicon layer overlying a silicon-germanium layer.

4. The semiconductor product of claim 1 wherein the third gate electrode material is a metal.

5. The semiconductor product of claim 4 wherein the third gate electrode material is selected from the group consisting of molybdenum, aluminum, nickel, tungsten, cobalt, and combinations thereof.

6. The semiconductor product of claim 1 wherein the third gate electrode material is a polycide.

7. The semiconductor product of claim 6 wherein the third gate electrode material is selected from the group consisting of tungsten, tantalum, molybdenum, nickel, cobalt, titanium silicides, and combinations thereof.

8. The semiconductor product of claim 6 wherein the third gate electrode material is formed of polysilicon.

9. The semiconductor product of claim 1 further comprising a first barrier layer interposed between the first gate electrode material layer and the second gate electrode material layer within the first transistor.

10. The semiconductor product of claim 1 further comprising a second barrier layer formed upon the second gate electrode material layer within the first transistor and the second transistor.

11. A semiconductor product comprising:
a semiconductor substrate having a first well of a first conductivity type and a second well of a second conductivity type;
a high-k gate dielectric layer formed upon the semiconductor substrate including the first well and the second well;
a first transistor formed with respect to the first well, the first transistor having a first gate comprising a first gate electrode material layer upon the high-k dielectric layer, a barrier layer upon the first gate electrode material layer and a second gate electrode material layer upon the
a second transistor formed with respect to the second well, the second transistor having a second gate comprising the second gate electrode material layer upon the high-k dielectric layer, the second gate electrode material layer having a second work function corresponding to the second well of the second conductivity type.

12. The semiconductor product of claim 11 further comprising a third gate electrode material layer upon the second gate electrode material layer within both the first transistor and the second transistor.

13. The semiconductor product of claim 12 wherein the third gate electrode material is selected from the group consisting of molybdenum, aluminum, nickel, tungsten, cobalt, and combinations thereof.

14. The semiconductor product of claim 12 wherein the third gate electrode material is a polycide.

15. The semiconductor product of claim 14 wherein the third gate electrode material is selected from the group consisting of tungsten, tantalum, molybdenum, nickel, cobalt, titanium silicides, and combinations thereof.

16. The semiconductor product of claim 12 wherein the third gate electrode material is formed of polysilicon.

17. The semiconductor product of claim 11 wherein the barrier layer is a metallic material.

18. The semiconductor product of claim 17 wherein the barrier layer is selected from the group consisting of titanium nitride, tantalum nitride, tungsten, and combinations thereof.

19. The semiconductor product of claim 1 further comprising:
a semiconductor substrate having a first well of a first conductivity type and a second well of a second conductivity type;
a high-k gate dielectric layer formed upon the semiconductor substrate including the first well and the second well;
a first transistor formed with respect to the first well, the first transistor having a first gate comprising a first gate electrode material layer upon the high-k dielectric layer, a first barrier layer upon the first gate electrode material layer, a second gate electrode material layer upon the first barrier layer and a second barrier layer upon the second gate electrode material layer, the first gate electrode material layer having a first work function corresponding to the first well of the first conductivity type;
a second transistor formed with respect to the second well, the second transistor having a second gate comprising the second gate electrode material layer upon the high-k dielectric layer and a second barrier layer upon the second gate electrode material layer, the second gate electrode material layer having a second work function corresponding to the second well of the second conductivity type.

20. A semiconductor product comprising:
a semiconductor substrate having a first well of a first conductivity type and a second well of a second conductivity type;
a first gate dielectric layer formed upon the semiconductor substrate at the location of the first well and a separate second gate dielectric layer formed upon the semiconductor substrate at the location of the second well;
a first transistor formed with respect to the first well, the first transistor having a first gate comprising a first gate electrode material layer upon the first gate dielectric layer, a second gate electrode material layer upon the first gate electrode material and a third gate electrode material upon the second gate electrode material;
a second transistor formed with respect to the second well, the second transistor having a second gate comprising the second gate electrode material layer upon the second gate dielectric layer and the third gate electrode material layer upon the second gate electrode material layer.
